(19) United States
(12) Patent Application Publication
(10) Pub. No.: US 2021/0351612 A1
(43) Pub. Date: Nov. 11, 2021

(54) SOLAR INVERTER POWER OUTPUT COMMUNICATIONS METHODS, AND RELATED COMPUTER PROGRAM PRODUCTS

(71) Applicant: Duke Energy Corporation, Charlotte, NC (US)

(72) Inventors: Sabin Jerome Fannin, Huntersville, NC (US); Justin Scott Hatcher, Belmont, NC (US); Eric Daniel Stone, Charlotte, NC (US); Kurt Brischke, Charlotte, NC (US)

(21) Appl. No.: 17/315,813

(22) Filed: May 10, 2021

Related U.S. Application Data
(60) Provisional application No. 63/051,659, filed on Jul. 14, 2020.
(60) Provisional application No. 63/022,928, filed on May 11, 2020.

(51) Int. Cl. H02J 13/00; H02J 3/38; G01R 31/40; G08B 21/18

(52) U.S. Cl. CPC H02J 13/00002; H02J 13/00001; H02J 2300/24; G01R 31/40; G08B 21/182; H02J 3/381

(57) ABSTRACT

Solar inverter power output communications methods are provided. A solar inverter power output communications method includes receiving, via a communications network, data regarding a plurality of solar power plants that include a plurality of solar inverters. The method includes identifying, based on the data, power output underperformance occurring at a first of the solar inverters. Moreover, the method includes providing an indication of the power output underperformance to a graphical user interface of an electronic device. Related computer program products are also provided.

### CROSS-REFERENCE TO RELATED APPLICATIONS

The present application claims priority to U.S. Provisional Patent Application Nos. 63/022,928, filed on May 11, 2020, and 63/051,659, filed on Jul. 14, 2020, the entire content of each of which is incorporated herein by reference.

### FIELD

The present disclosure relates to communications methods and to solar inverters.

### BACKGROUND

A photovoltaic (“PV”) system, which may also be referred to as a “solar power system,” uses PVs to supply power. The PV system includes solar panels that absorb and convert sunlight into electricity. The PV system also includes a solar inverter to convert an output of the panels from direct current (“DC”) to alternating current (“AC”). Moreover, the PV system may include a solar tracker to orient one or more of the panels toward the sun. For example, a tracker may adjust the tilt of a panel throughout the day to keep the panel facing the sun.

A solar power plant may include multiple PV systems, and thus multiple solar inverters. Power output performance may vary across different solar inverters, such as (a) across different solar inverters that are at the same solar power plant and/or (b) across different solar inverters that are at different solar power plants. This variability can make it difficult to track performance across a large number of solar inverters. Moreover, performance data for solar inverters may be reported intermittently/inconsistently, which can make it difficult to isolate event losses (e.g., events causing power-output underperformance) and types/trends of event loss with respect to solar inverters.

### SUMMARY

A method, according to some embodiments herein, may include receiving, via a communications network, data regarding a plurality of solar power plants that include a plurality of solar inverters. The method may include identifying, based on the data, power output underperformance occurring at a first of the solar inverters. Moreover, the method may include providing an indication of the power output underperformance to a graphical user interface (“GUI”) of an electronic device that is communicatively coupled to the communications network or to a different communications network.

In some embodiments, the identifying may include: comparing, based on the data, actual power output by the first of the solar inverters with expected power output by the first of the solar inverters; and determining, based on the comparing, that the actual power output is lower than the expected power output. Moreover, the method may include identifying adequate power output performance occurring at a second of the solar inverters by: comparing, based on the data, actual power output by the second of the solar inverters with expected power output by the second of the solar inverters; and determining, based on the comparing, that the actual power output by the second of the solar inverters meets or exceeds the expected power output by the second of the solar inverters.

According to some embodiments, the method may include identifying complete power output failure by a third of the solar inverters. Moreover, the identifying the complete power output failure may include: comparing, based on the data, actual power output by the third of the solar inverters with expected power output by the third of the solar inverters; and determining, based on the comparing, that the actual power output by the third of the solar inverters is zero and that the expected power output by the third of the solar inverters is greater than zero.

In some embodiments, the method may include identifying power output underperformance occurring at a fourth of the solar inverters by: comparing, based on the data, actual power output by the fourth of the solar inverters with expected power output by the fourth of the solar inverters; and determining, based on the comparing, that the actual power output by the fourth of the solar inverters is lower than the expected power output by the fourth of the solar inverters. The first through fourth solar inverters may at different first through fourth of the solar power plants, respectively. Alternatively, at least three of the first through fourth solar inverters may be at the same one of the solar power plants.

According to some embodiments, the identifying power output underperformance occurring at the first of the solar inverters may include: inputting the data into a plurality of deep-learning (and/or business-logic) models; and applying, using the data, the deep-learning (and/or business-logic) models to each of the solar inverters. The applying may include classifying, by the deep-learning (and/or business-logic) models, a difference between actual power output by the first of the solar inverters and expected power output by the first of the solar inverters.

In some embodiments, the classifying may include: comparing first data indicating actual power output by the first of the solar inverters during a first time period with expected power output by the first of the solar inverters during the first time period; and comparing second data indicating actual power output by the first of the solar inverters during a second time period with expected power output by the first of the solar inverters during the second time period. The first and second time periods may each be a plurality of minutes, and the data may include solar irradiance data that indicates solar irradiance at a solar array that is coupled to the first of the solar inverters.

According to some embodiments, the classifying may include providing a plurality of outputs from the deep-learning (and/or business-logic) models, respectively, to a further model that processes the outputs and provides a final classification for the first of the solar inverters.

In some embodiments, the data may be received via the communications network from a plurality of nodes that are adjacent and coupled to the solar inverters, respectively.

According to some embodiments, the communications network may include a cellular network or a fiber network. Moreover, the method may include: sending, via the cellular network or the fiber network, a plurality of authentication tokens to the nodes, or to central nodes that are communicatively coupled to the nodes, before the data is received; or sending, via the cellular network or the fiber network, a command to increase or decrease power that is output by the first of the solar inverters, in response to the identifying.

A method, according to some embodiments herein, may include receiving, via a communications network, first and second actual power output data indicating actual power output by first and second solar inverters, respectively, that are at a first solar power plant. The method may include receiving, via the communications network, third and fourth actual power output data indicating actual power output by third and fourth solar inverters, respectively, that are at a second solar power plant. The method may include comparing, as a first comparison, the first actual power output data with first expected power output data indicating expected power output by the first solar inverter. The method may include comparing, as a second comparison, the second actual power output data with second expected power output data indicating expected power output by the second solar inverter. The method may include comparing, as a third comparison, the third actual power output data with third expected power output data indicating expected power output by the third solar inverter. The method may include comparing, as a fourth comparison, the fourth actual power output data with fourth expected power output data indicating expected power output by the fourth solar inverter. Moreover, the method may include identifying, based on the first through fourth comparisons, power output underperformance occurring at one or more of the first through fourth solar inverters.

In some embodiments, the method may include: using machine learning and/or business logic to classify the power output underperformance into one or more among a plurality of predetermined classifications; and providing an indication of the power output underperformance to a GUI of an electronic device.

According to some embodiments, the first through fourth actual power data may be received via the communications network from first through fourth nodes that are adjacent and coupled to the first through fourth solar inverters, respectively. The communications network may include a cellular network or a fiber network. Moreover, the method may include sending, via the cellular network or the fiber network, authentication tokens to the first through fourth nodes, or to central nodes that are communicatively coupled to the first through fourth nodes, before the first through fourth actual power output data are received.

A computer program product, according to some embodiments herein, may include a non-transitory computer readable storage medium including computer readable program code embodied in the medium. The computer readable program code may include computer readable program code configured to apply, using data regarding a plurality of solar inverters that are at a plurality of solar power plants, a machine-learning (and/or business-logic) model to each of the solar inverters to identify power output underperformance occurring at one or more of the solar inverters.

In some embodiments, the computer readable program code may be configured to identify the power output underperformance by: comparing, as a first comparison, first actual power output data indicating actual power output by a first of the solar inverters that is at a first of the solar power plants with first expected power output data indicating expected power output by the first of the solar inverters; comparing, as a second comparison, second actual power output data indicating actual power output by a second of the solar inverters that is at the first of the solar power plants with second expected power output data indicating expected power output by the second of the solar inverters; comparing, as a third comparison, third actual power output data indicating actual power output by a third of the solar inverters that is at a second of the solar power plants with third expected power output data indicating expected power output by the third of the solar inverters; comparing, as a fourth comparison, fourth actual power output data indicating actual power output by a fourth of the solar inverters that is at the second of the solar power plants with fourth expected power output data indicating expected power output by the fourth of the solar inverters; and providing, based on the first through fourth comparisons, an indication of the power output underperformance to a GUI of an electronic device.

### BRIEF DESCRIPTION OF THE DRAWINGS

FIG. 1A is a schematic illustration of solar power plants that provide output power to a distribution network, according to embodiments of the present inventive concepts.

FIG. 1B is a detailed schematic illustration of a first solar power plant of FIG. 1A.

FIG. 1C is a detailed schematic illustration of a second solar power plant of FIG. 1A.

FIGS. 1D and 1E are detailed schematic illustrations of communications with the solar power plants of FIG. 1A.

FIG. 1F is a block diagram of a node of any of FIGS. 1A-1E.

FIG. 1G is a block diagram that illustrates details of an example processor and memory that may be used in accordance with various embodiments.

FIG. 1H is a block diagram of a solar inverter of any of FIGS. 1B or 1C.

FIG. 1I is a schematic illustration of a room of an office (or data center) of FIG. 1A.

FIGS. 2A-2E are flowcharts of operations of solar inverter power output communications methods, according to embodiments of the present inventive concepts.

FIG. 3 is a screenshot of a GUI of an electronic device that is communicatively coupled to the communications network of FIG. 1A or to a different communications network.

### DETAILED DESCRIPTION

Pursuant to embodiments of the present inventive concepts, event losses at solar power plants can be detected, communicated, and diagnosed. Event losses may be, for example, instances where solar inverters do not produce energy as they should. Though conventional systems may provide sufficient data to identify losses, it can be difficult to determine the cause of such losses. According to embodiments of the present inventive concepts, however, communications methods, tools, and user interfaces can be provided that facilitate identifying and classifying event losses.

For example, machine-learning (i.e., artificial-intelligence and/or business-logic) models can be trained to identify and classify event losses at solar power plants. As an example, deep-learning (and/or business-logic) models may provide an open-source base framework that can be trained to classify types of event losses and to identify event-loss trends. In particular, data can be (i) received from a plurality of solar power plants and (ii) input to a plurality of deep-learning (and/or business-logic) models, where the data can be analyzed with respect to every solar inverter that is at the solar power plants. As a result, for each solar inverter, (a) expected loss can be compared with (b) actual loss, and a determination can be made about whether and how a loss event is happening. The models, along with user-friendly user interfaces, can thus help prioritize, and understand the cause of, event losses. Moreover, a further model can track event-loss trends over time (e.g., weeks, months, or longer), thus facilitating improved/optimized performance. As used herein, the term “event loss” refers to lost energy, such as the difference between actual and expected energy. Moreover, an event loss may have a deep-learning (and/or business-logic) model derived classification attributed to an asset (e.g., site or inverter) or collection of assets over a specified time period.

Example embodiments of the present inventive concepts will be described in greater detail with reference to the attached figures.

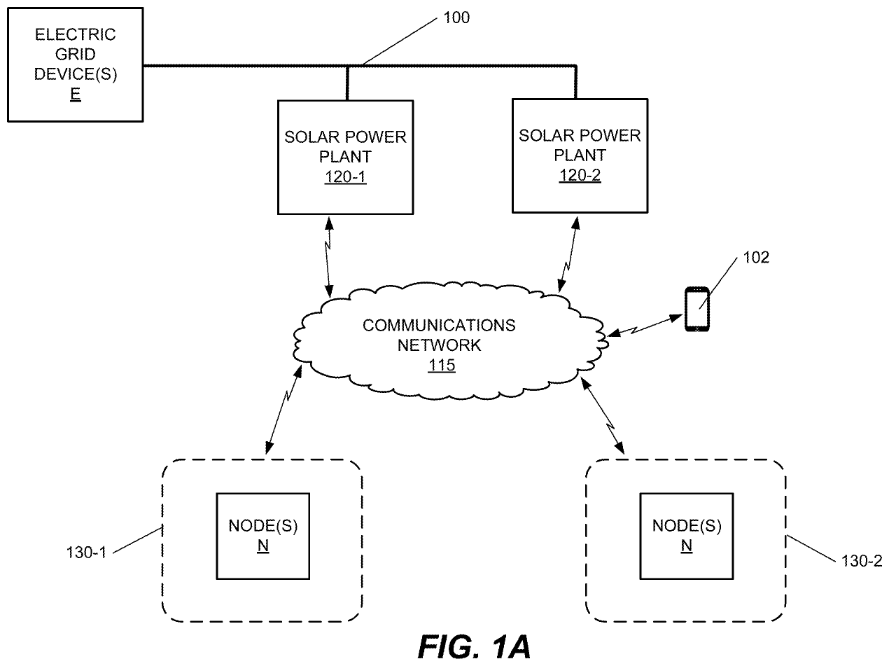

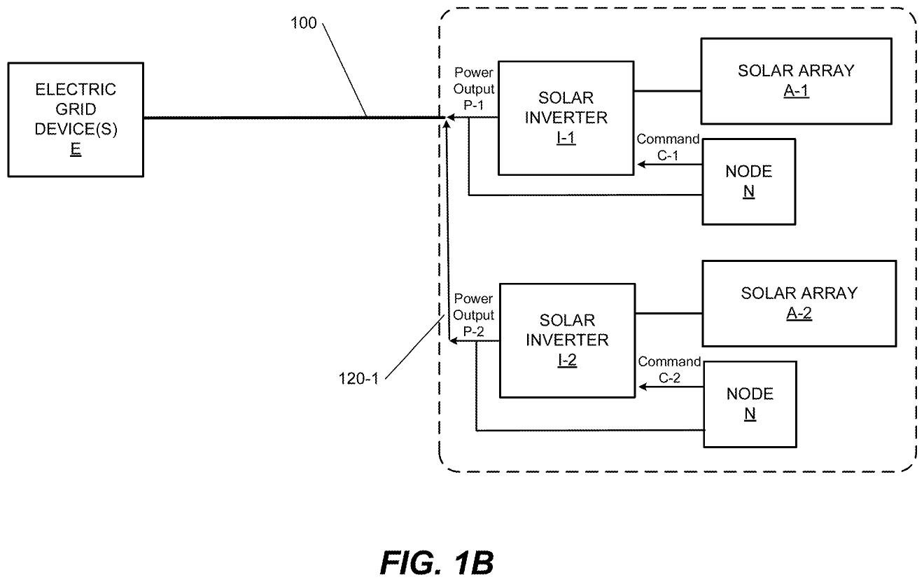

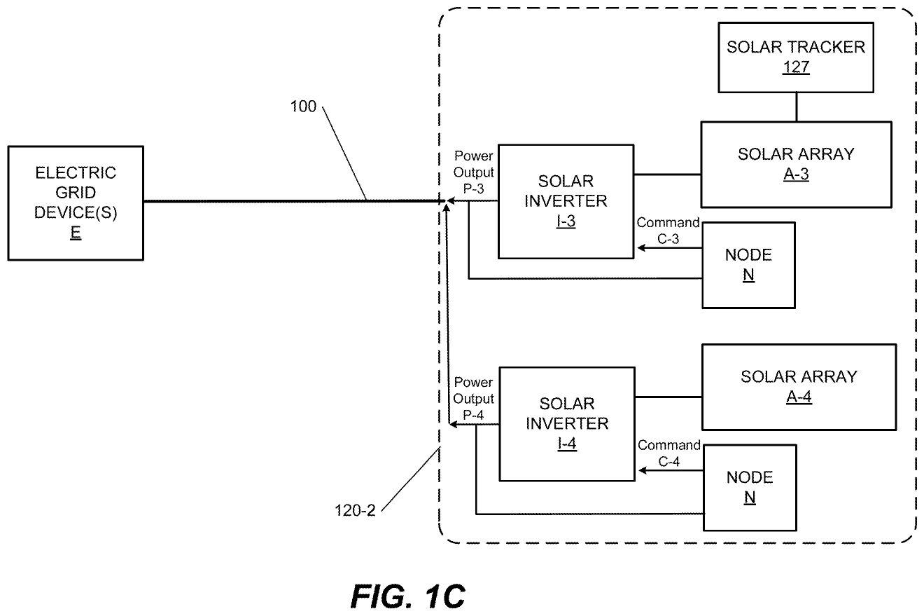

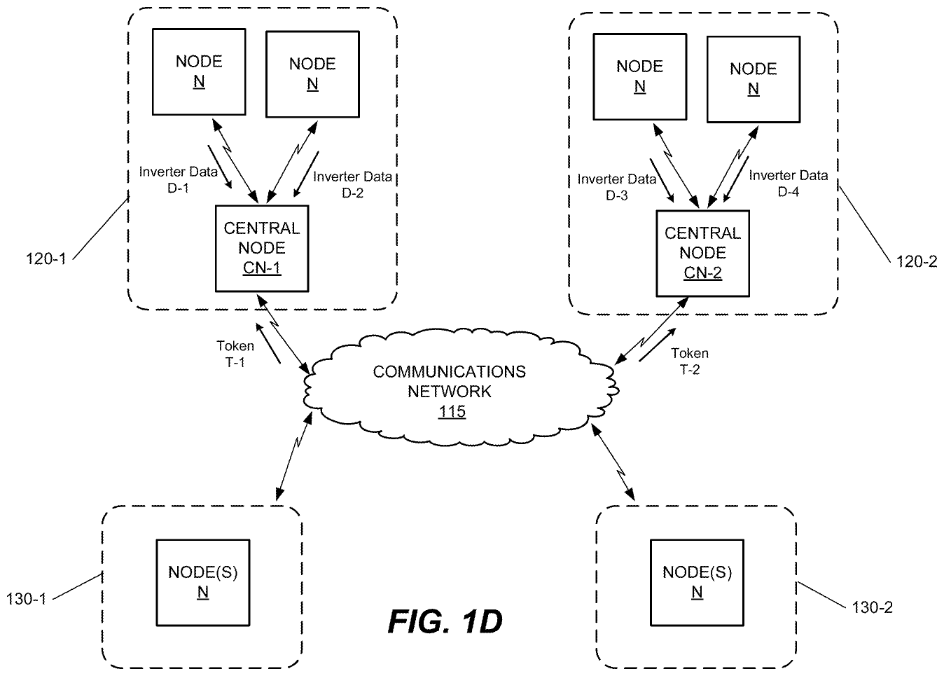

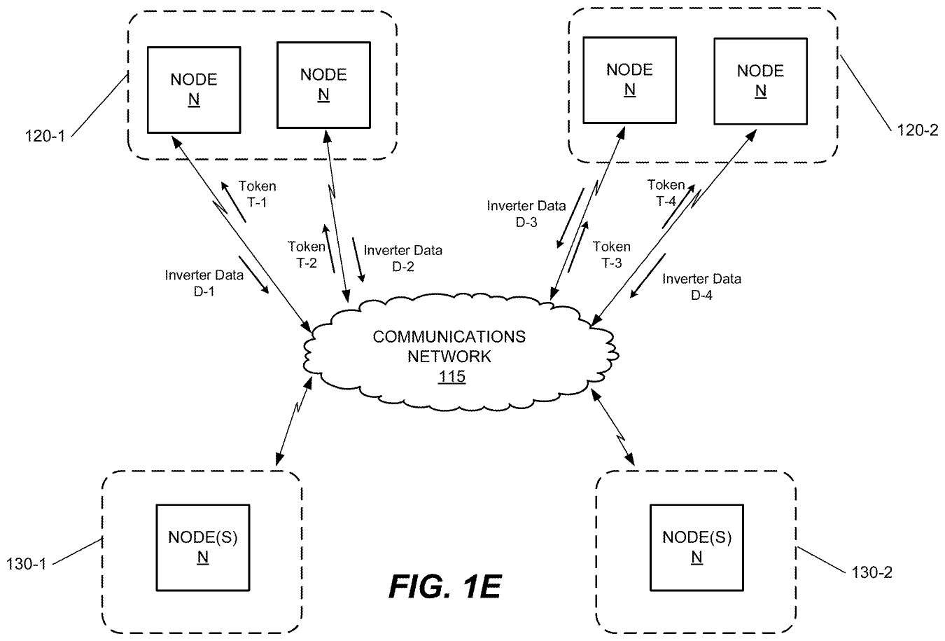

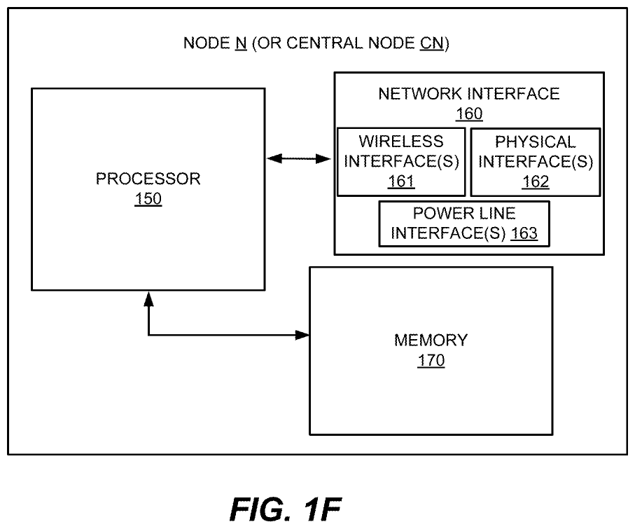

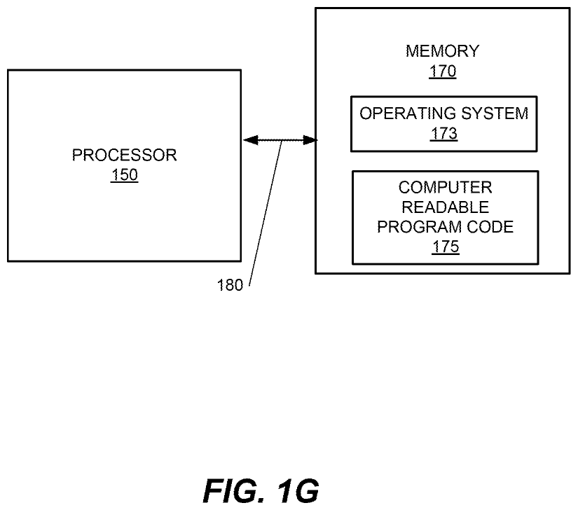

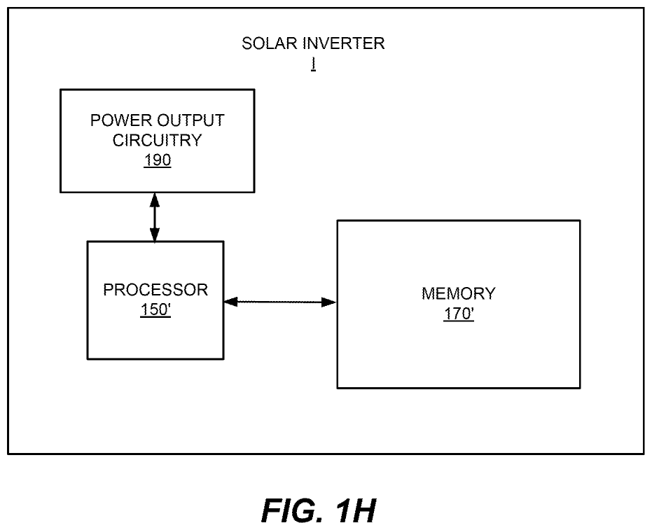

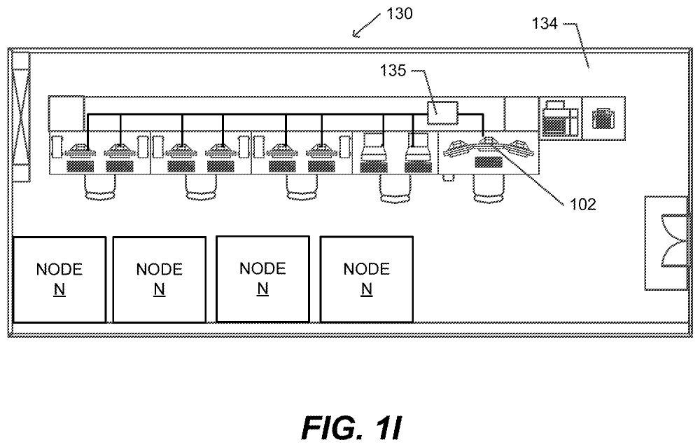

FIG. 1A is a schematic illustration of solar power plants 120 that each provide an electrical energy output (e.g., a power output) to a distribution network/circuit that is connected to many customers of an electric utility. For example, the plants 120 may provide their power outputs to an electric grid 100 that may include any number of electric grid devices E. In some embodiments, one or more of the plants 120 may additionally or alternatively provide a power output to a local, off-grid electrical network.

The plants 120 may communicate with one or more data centers 130 via a communications network 115. Each data center 130 may have one or more nodes N that can use power output data from the plants 120 to identify, classify, and respond to power output underperformance. For simplicity of illustration, only two plants 120-1 and 120-2 are shown in FIG. 1A. Three, four, or more plants 120, however, may provide power outputs to the grid 100 and may communicate with the data center(s) 130 via the communications network 115. Likewise, though two data centers 130-1 and 130-2 are shown, one, three, four, or more data centers 130 may communicate with the plants 120 via the communications network 115.

The communications network 115 may include one or more wireless or wired communications networks, such as a local area network (e.g., Ethernet or Wi-Fi), a cellular network, a power-line communication (“PLC”) network, and/or a fiber (such as a fiber-optic) network. In some embodiments, an electronic device 102 may be communicatively coupled to the communications network 115. For example, the electronic device 102 may be communicatively coupled to a cellular or fiber network that couples the data centers 130 to the plants 120, or may be coupled to a different cellular or fiber network. The electronic device 102 may be located (a) at a plant 120, (b) inside a data center 130, or (c) outside of any plant 120 or data center 130. For simplicity of illustration, only one electronic device 102 is shown in FIG. 1A. A plurality of electronic devices 102, however, may be provided at various locations, and the electronic devices 102 may comprise desktop computers, laptop computers, tablet computers, and/or smartphones.

An electric grid device E may be, for example, an electric utility meter, a transformer, a light (e.g., a street light), an electric grid control device, an electric grid protection device, a recloser, a line sensor, a weather sensor, an advanced metering infrastructure (“AMI”) device, an analog or digital sensor connected to an electric utility asset, an electric generator, an electric turbine, an electric boiler, an electric vehicle, a home appliance, a battery storage device, a capacitor device, a smart generation device, an intelligent switching device, an emission monitoring device, or a voltage regulator.

FIG. 1B is a detailed schematic illustration of a first solar power plant 120-1 of FIG. 1A. The first plant 120-1 includes a plurality of solar inverters I that are coupled to a plurality of solar arrays A, respectively. The solar arrays A, which may also be referred to as “PV arrays,” each include a plurality of PV modules, which may also be referred to as “solar panels,” that use sunlight to generate DC electricity. The solar inverters I are configured to convert the DC electricity from the arrays A to AC electricity. For example, a first solar inverter I-1 may provide a first AC power output P-1 to the grid 100. Similarly, a second solar inverter I-2 may provide a second AC power output P-2 to the grid 100.

For simplicity of illustration, only two inverters I-1 and I-2 are shown in FIG. 1B. In some embodiments, however, each plant 120 may be a large, utility-scale power station having a power output of hundreds of megawatts. Accordingly, the first plant 120-1 may include three or more (e.g., dozens, hundreds, or thousands of) inverters I. Likewise, the first plant 120-1 may also include three or more arrays A. Moreover, some of the inverters I may be coupled to individual solar panels, respectively, rather than to respective arrays A that each include multiple solar panels.

The inverters I may also be coupled to respective nodes N, which may be electronic devices that are configured to measure and/or communicate measured power outputs P on behalf of the inverters I. For example, the nodes N may transmit data indicating the power outputs P-1 and P-2 to one or more data centers 130 (FIG. 1A) via a communications network 115 (FIG. 1A). Moreover, the nodes N may receive and/or generate commands C-1 and C-2 for the solar inverters I. As an example, one or more of the data centers 130 may transmit the commands C-1 and C-2 to the nodes N via the communications network 115 to increase or decrease power (e.g., a power level) that is output by the inverters I. In some embodiments, the nodes N may be Internet-of-things (“IOT”) devices that can communicate with the inverters I and the data center(s) 130 without requiring human-to-human or human-to-computer interaction. For simplicity of illustration, the data centers 130 and the communications network 115 are omitted from view in FIG. 1B.

FIG. 1C is a detailed schematic illustration of a second solar power plant 120-2 of FIG. 1A. Similar to the first plant 120-1 (FIG. 1B), the second plant 120-2 may include a plurality of inverters I that are coupled to a plurality of arrays A, respectively. For example, the second plant 120-2 may include inverters I-3 and I-4 that are coupled to arrays A-3 and A-4, respectively. The inverters I-3 and I-4 may provide AC power outputs P-3 and P-4, respectively, to the electric grid 100. Moreover, the inverters I-3 and I-4 may be coupled to respective nodes N that can transmit data indicating the power outputs P-3 and P-4 to one or more data centers 130 (FIG. 1A), and/or can provide commands C-3 and C-4 to the inverters I-3 and I-4, respectively.

FIG. 1C further illustrates that the array A-3 is coupled to a solar tracker 127, which adjusts the tilt of panels of the array A-3 to face the sun. For simplicity of illustration, only one tracker 127 is shown in FIG. 1C. Multiple arrays A, however, can be coupled to respective trackers 127. As an example, the arrays A-3 and A-4 may be coupled to respective trackers 127. Additionally or alternatively, arrays A-1 and A-2 (FIG. 1B) may be coupled to respective trackers 127. As used herein, the term “array” refers to a grouping of solar modules (e.g., a grouping of solar panels).

FIGS. 1D and 1E are detailed schematic illustrations of communications with the plants 120-1 and 120-2 of FIG. 1A. Specifically, FIGS. 1D and 1E illustrate different embodiments of transmitting plant (e.g., inverter) data D-1 through D-4 indicating power outputs P-1 through P-4, respectively, of inverters I-1 through I-4 (FIGS. 1B and 1C) of the plants 120-1 and 120-2. For simplicity of illustration, the inverters I and arrays A (FIGS. 1B and 1C) of the plants 120-1 and 120-2 are omitted from view in FIGS. 1D and 1E.

Though the data D-1 through D-4 are illustrated in FIGS. 1D and 1E as comprising inverter data, it will be understood that additional data sources at the plants 120-1 and 120-2 may provide plant data D that can be used to identify power output underperformance. For example, one or more current transducers installed on one or more conductors, respectively, originating from the plant 120-1 and/or the plant 120-2 may provide plant data D comprising current that is measured by the transducer(s). As another example, a single-axis tracking system may provide plant data D comprising an expected angle and/or an actual angle of all or a portion of the solar panels installed at a solar plant 120. The term “solar panel,” as used herein, refers to a single PV module that converts sunlight energy into DC electricity. The current transducer and/or the tracking system may, in some embodiments, be implemented as (or as part of) a node N.

FIG. 1D illustrates an embodiment in which the nodes N that are at the plants 120 communicate with the communications network 115 via central nodes CN that are at the plants 120. FIG. 1E, on the other hand, illustrates an embodiment in which each node N at the plants 120 communicates directly (i.e., without using a central node CN as an intermediary) with the communications network 115. Referring to FIG. 1D, each plant 120 may have a central node CN, which may be a gateway/central server. The central node CN may communicate with the nodes N that are at the plant 120 via a wired (e.g., fiber, PLC, universal serial bus (“USB”), or wired Ethernet) connection or a wireless (e.g., Wi-Fi or BLUETOOTH®) connection. The central node CN may also communicate with one or more data centers 130 via the communications network 115.

In particular, a first central node CN-1 that is at the plant 120-1 can receive the plant (e.g., inverter) data D-1 and D-2 from respective nodes N that are at the plant 120-1, and can then transmit the plant data D-1 and D-2 to one or more data centers 130 via the communications network 115. Likewise, a second central node CN-2 that is at the plant 120-2 can receive the plant (e.g., inverter) data D-3 and D-4 from respective nodes N that are at the plant 120-2, and can then transmit the plant data D-3 and D-4 to one or more data centers 130 via the communications network 115.

The central nodes CN can also receive authentication tokens T from the data center(s) 130 via the communications network 115. For example, the central node CN-1 may receive a first authentication token T-1 that authorizes the central node CN-1 to transmit the plant data D-1 and D-2 via the communications network 115. Similarly, the central node CN-2 may receive a second authentication token T-2 that authorizes the central node CN-2 to transmit the plant data D-3 and D-4 via the communications network 115. Alternatively, each node N may need to provide a respective token T to its central server CN to enable communications from the node N through the central server CN to the communications network 115.

Referring to FIG. 1E, nodes N at each plant 120 may communicate with the communications network 115 without using a gateway/central server at each plant 120 as an intermediary. Accordingly, four nodes N may receive four authentication tokens T-1 through T-4, respectively, from the data center(s) 130 directly from the communications network 115. The nodes N may also transmit the plant data D-1 through D-4 directly to the communications network 115.

In some embodiments, each token T shown in FIGS. 1D and 1E may be a unique token that enables transmission of plant (e.g., inverter) data D of a respective inverter I. Accordingly, the central node CN-1 (FIG. 1D) may be unable to use the token T-2 to transmit the plant data D-1 and D-2. Similarly, a node N shown in FIG. 1E may be unable to use the token T-4 to transmit the plant data D-3. Alternatively, each token T may be identical, or the tokens T-1 and T-2 shown in FIG. 1E for the plant 120-1 may be identical and the tokens T-3 and T-4 for the plant 120-2 may be identical but different from the tokens T-1 and T-2.

FIG. 1F is a block diagram of a node N of any of FIGS. 1A-1E (or a central node CN of FIG. 1D). The node N may include a processor 150, a network interface 160, and a memory 170. The processor 150 of the node N may be coupled to the network interface 160. The processor 150 may be configured to communicate with an inverter I (FIGS. 1B and 1C), the communication network 115 (FIG. 1A), and/or a central node CN via the network interface 160.

For example, the network interface 160 may include one or more wireless interfaces 161 and/or one or more physical interfaces 162. The wireless interface(s) 161 may comprise wireless communications circuitry, such as BLUETOOTH® circuitry, cellular communications circuitry that provides a cellular wireless interface (e.g., 4G/5G/LTE, other cellular), and/or Wi-Fi circuitry. The physical interface(s) 162 may comprise wired communications circuitry, such as wired Ethernet, serial, and/or USB circuitry. Moreover, the network interface 160 may include one or more power line interfaces 163, which may comprise PLC circuitry.

FIG. 1G is a block diagram that illustrates details of an example processor 150 and memory 170 that may be used in accordance with various embodiments. The processor 150 communicates with the memory 170 via an address/data bus 180. The processor 150 may be, for example, a commercially available or custom microprocessor. Moreover, the processor 150 may include multiple processors. The memory 170 may be a non-transitory computer readable storage medium and may be representative of the overall hierarchy of memory devices containing the software and data used to implement various functions of a node N (FIGS. 1A-1E or 1I), a central node CN (FIG. 1D), or an electronic device 102 (FIGS. 1A and 1I) as described herein. The memory 170 may include, but is not limited to, the following types of devices: cache, ROM, PROM, EPROM, EEPROM, flash, static RAM (“SRAM”), and dynamic RAM (“DRAM”).

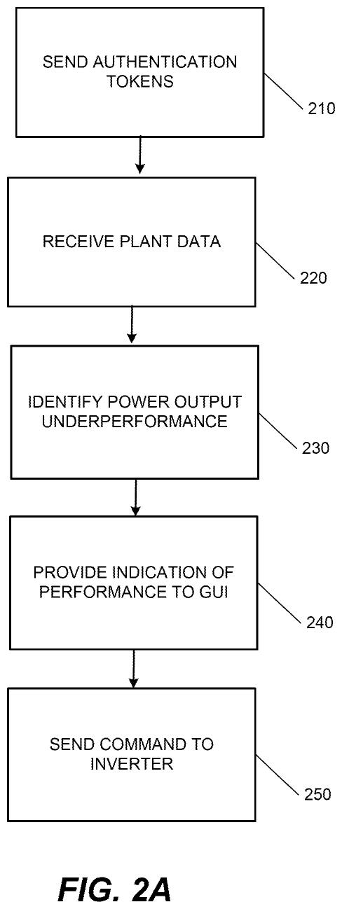

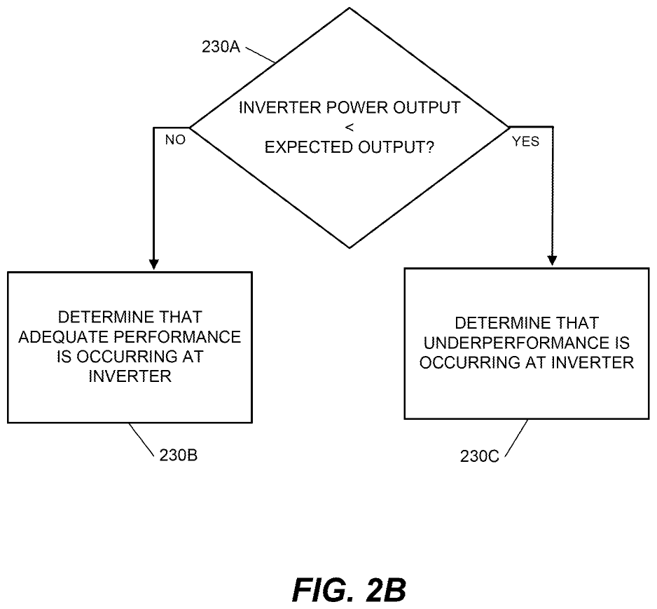

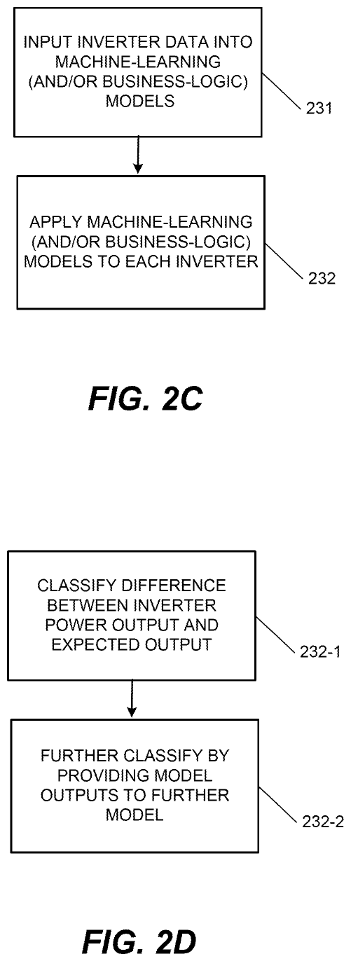

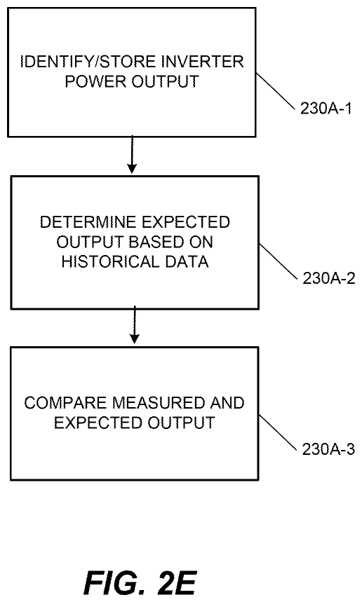

As shown in FIG. 1G, the memory 170 may hold various categories of software and data, such as computer readable program code 175 and/or an operating system 173. The operating system 173 controls operations of a node N, a central node CN, or an electronic device 102. In some embodiments, the operating system 173 may manage the resources of the node N, the central node CN, or the electronic device 102 and may coordinate execution of various programs by the processor 150. For example, the computer readable program code 175, when executed by a processor 150 of the node N or the electronic device 102, may cause the processor 150 to perform any of the operations illustrated in the flowcharts of FIGS. 2A-2E.

FIG. 1H is a block diagram of an inverter I of any of FIGS. 1B or 1C. The inverter I may include power output circuitry 190. In some embodiments, the inverter I may further include a processor 150′ and/or a memory 170′, which may be similar to a processor 150 and a memory 170, respectively, described herein. The power output circuitry 190 may include, for example, various types of circuitry configured to convert a DC output of a solar panel (or from an array A (FIGS. 1B and 1C) of solar panels) into a utility-frequency AC output that can be fed into a commercial electrical grid (e.g., the grid 100 (FIG. 1A)) or used by a local, off-grid electrical network. For example, the power output circuitry 190 may be configured to provide a power output P illustrated in FIG. 1B or FIG. 1C.

FIG. 11 is a schematic illustration of a room 134 of a data center (or office) 130. The room 134 may include one or more nodes N that may communicate via a communications network 115 (FIG. 1A) with nodes N of one or more plants 120 (FIG. 1A). The room 134 may also include one or more electronic devices 102 that can communicate with the node(s) N in the room 134 via a local area network (“LAN”) 135. Additionally or alternatively, an electronic device 102 may communicate via the LAN with one or more nodes N that are in a different room of the data center 130. In some embodiments, the LAN 135 may comprise a wired and/or wireless (e.g., Wi-Fi) Ethernet network that connects electronic devices 102 that are inside the data center 130 (a) to each other, (b) to nodes N that are inside the data center 130, and/or (c) to the communication network 115. The electronic devices 102 may comprise desktop computers, laptop computers, tablet computers, and/or smartphones. Accordingly, a human user, such as an electric utility employee or contractor, may provide user inputs to an electronic device 102 to communicate with one or more nodes N that are inside the data center 130.

In some embodiments, a human user may provide user inputs to an electronic device 102 to communicate with one or more nodes N that are inside a different data center 130. For example, the electronic device 102 may be inside the data center 130-1 (FIG. 1A) and may communicate via the communications network 115 with one or more nodes N that are inside the data center 130-2 (FIG. 1A).

Though four nodes N are shown in FIG. 1I, the data center 130 may include one, two, three, five, or more nodes N. Moreover, the nodes N that are inside the data center 130 may, in some embodiments, be respective servers that can each host one or more machine-learning (and/or business-logic) models. Accordingly, a human user may use an electronic device 102 to provide inputs to the machine-learning model(s) and/or to receive outputs from the machine-learning model(s).

Data D (FIGS. 1D and 1E) regarding power outputs P by inverters I (FIGS. 1B and/or 1C) may be fed from nodes N that are at the plants 120 to servers, such as nodes N that are at two different data centers 130-1 and 130-2. In some embodiments, multiple servers may run machine-learning (and/or business-logic) models that analyze the data D and provide outputs to a table, which provides outputs to a database, which then provides outputs to one or more Internet/mobile applications.

FIGS. 2A-2E are flowcharts of operations of solar inverter power output communications methods. Referring to FIG. 2A, the operations include receiving (Block 220), via a communications network 115 (FIG. 1A), plant data D (FIG. 1D or FIG. 1E) regarding a plurality of plants 120 (FIG. 1A) having a plurality of inverters I (FIGS. 1B and 1C). For example, the data D may comprise inverter data, and one or more nodes N (FIG. 1A) at one or more data centers 130 (FIG. 1A) may receive the data D from a plurality of nodes N (FIGS. 1B and 1C) that are adjacent and/or communicatively coupled to the inverters I, respectively. Additionally or alternatively, the node(s) N at the data center(s) 130 may receive data D regarding one or more of the plants 120 from one or more non-inverter data sources, such as a current transducer and/or a single-axis tracking system.

The data D may include indications of power outputs P (FIGS. 1B and 1C) of the inverters I. As an example, the data D may include values of measurements of power outputs P of the inverters I. Moreover, the data D may further include various other information about a plant 120, and thus may be referred to herein as “plant information.” For example, the data D may include information about solar irradiance (e.g., a brightness value of the sun). As an example, a node N that is at the plant 120 and is adjacent (but not necessarily communicatively-coupled to) an inverter I may comprise a sensor that detects solar irradiance for a panel/array A (FIGS. 1B and 1C) that is coupled to the inverter I.

Accordingly, operations of solar inverter power output communications methods also include identifying (Block 230), based on the data D, power output P underperformance (or a complete failure or adequate performance) occurring at one or more of the inverters I. Moreover, the data D may further include identification information of the inverters I. For example, identification information of an inverter I may include a model number, a manufacturer/brand name, a geographic position, and/or a serial number of the inverter I. Such information can also be tracked for other assets at plants 120, including panels/arrays A and trackers 127 (FIG. 1C). This can help to determine which assets perform well and which do not. In some embodiments, message authentication information may be transmitted along with the data D. As an example, an authentication token T (FIG. 1D or FIG. 1E) may be received at a plant 120 and then transmitted from the plant 120 (e.g., from a node N) along with the data D.

A node N at a plant 120 may, in some embodiments, comprise a combiner box that is coupled to multiple arrays A and is configured to track energy provided by the arrays A. Moreover, the combiner box can transmit separate energy data for each array A.

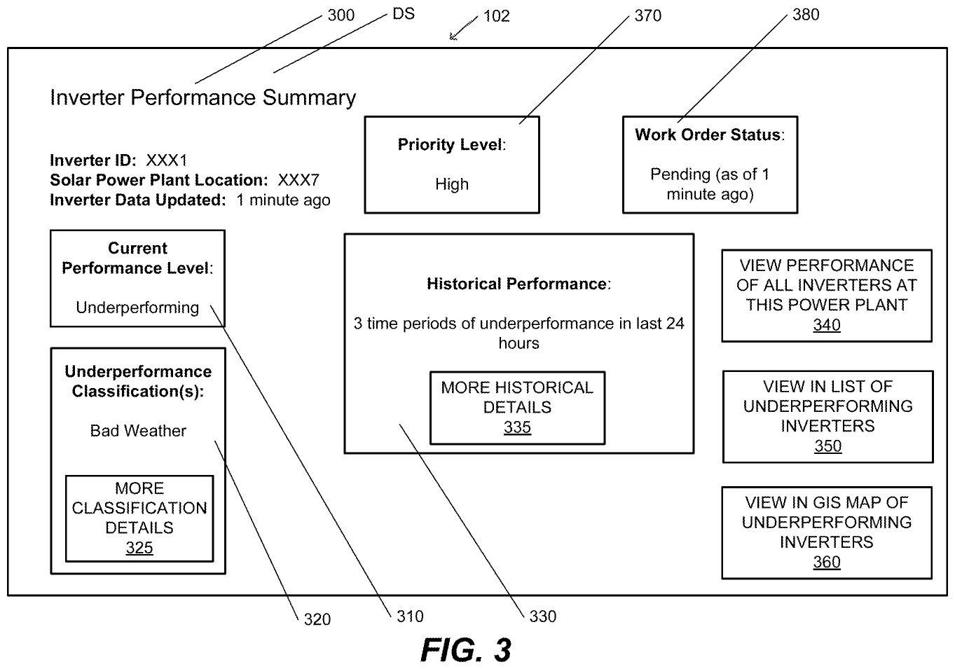

In some embodiments, operations of solar inverter power output communications methods may also include providing (Block 240) an indication of the power output P underperformance to a GUI 300 (FIG. 3) of an electronic device 102 (FIG. 1A or FIG. 11). For example, the indication of the power output P underperformance may be generated, and transmitted via a LAN 135 (FIG. 11), by a node N (FIG. 11) that is at the same data center 130 (FIG. 11) as the electronic device 102. As another example, the indication of the power output P underperformance may be generated, and transmitted via the communications network 115, by a node N that is at a different data center 130 from the electronic device 102.

Moreover, the electronic device 102 is not limited to being inside a data center 130. Accordingly, the electronic device 102 may, in some embodiments, receive the indication of the power output P underperformance via the communications network 115 while the electronic device 102 is outside of any data center 130. For example, the indication of the power output P underperformance may be provided to the electronic device 102 as part of a cloud-based service in which one or more data centers 130 receive data from third parties and respond to the third parties with underperformance results. Additionally or alternatively, the indication of the power output P underperformance may be provided via a cellular or fiber network to an electronic device 102 of a member of a field crew, as a part of a service request that is issued to the field crew to address underperformance in the field (e.g., at a plant 120).

Referring still to FIG. 2A, operations of solar inverter power output communications methods may further include sending (Block 250), via the communications network 115, a command C (FIGS. 1B and 1C) to increase or decrease the power output P of at least one inverter I. For example, a node N that is inside a data center 130 may transmit the command C to a node N that is at a plant 120 and communicatively coupled to an inverter I. In particular, the command C may be transmitted in response to identifying power output P underperformance occurring at the inverter I. In some embodiments, the command C may instruct the inverter Ito reduce its power output P to zero.

Operations of solar inverter power output communications methods may additionally or alternatively include sending (Block 210), via the communications network 115, authentication tokens T (FIG. 1D or FIG. 1E) that can be used to enable/authenticate transmissions of data D. As an example, a node N that is inside a data center 130 may transmit tokens T to nodes N (or to central nodes CN (FIG. 1D)) that are at plants 120. Moreover, the nodes N (or the central nodes CN) that are at plants 120 may subsequently transmit, via the communications network 115, the tokens T (e.g., along with the data D) to one or more nodes N that are inside one or more data centers 130.

Referring to FIG. 2B, operations of identifying (Block 230 of FIG. 2A) power output P underperformance may include comparing (Block 230A), based on data D received from plants 120, (a) actual power output P (e.g., a measured value in kilowatts) by an inverter I with (b) an expected power output (e.g., a predetermined or retroactively-calculated value in kilowatts) by the inverter I. Based on this comparison, a determination can be made of whether adequate power output P performance is occurring at the inverter I (Block 230B) or power output P underperformance is occurring at the inverter I (Block 230C). For example, the comparison may result in a determination that underperformance is occurring at the inverter I because its actual power output P is lower by ten percent or more than its expected power output. The expected power output may be indicated by (and/or determined/calculated using) historical data that was received and/or generated by one or more data centers 130 with respect to the inverter I before receiving the data D. Moreover, in some embodiments, a determination of the expected power output may be performed, using the historical data, responsive to (and thus after) receiving the data D. If the actual power output P of the inverter I is zero (or otherwise more than ninety percent below expectation) and its expected power output is greater than zero, then it may be determined that the inverter I has a complete power output failure. On the other hand, the comparison may result in a determination of adequate performance occurring at the inverter I if its actual power output P meets or exceeds its expected power output.

Such comparisons may, in some embodiments, be performed only with respect to predetermined time windows of equal duration. For example, a first comparison may be performed using first data D that covers a twenty-four-hour time window of output by an inverter I, and a subsequent comparison may likewise be performed with respect to second data D that covers a different twenty-four-hour time window for the inverter I.

Expected power output may, in some embodiments, be different from a power output prediction/forecast. For example, expected power output by an inverter I may be determined/calculated retroactively, such as after (or concurrently with) measuring actual power output P by the inverter I. In particular, the retroactive determination/calculation may consider historical power output data for the inverter I and may exclude any prediction/forecast of future power output by the inverter I.

The historical data may comprise first data among the data D that overlaps in time (at which it is generated/measured at the plant(s) 120) second data among the data D that the measured actual power output P is based on, and/or may comprise third data that precedes (e.g., that covers output time windows before that of) the second data. The historical data does not, however, include the measured value of the actual power output P itself. Rather, a value of the expected power output may be determined using solar irradiance data for a panel/array A (FIGS. 1B and 1C) that is coupled to the inverter I and/or using other historical data. For example, the solar irradiance data may indicate solar irradiance at the panel/array A during the same time window for which the actual power output P is measured (e.g., the last twenty-four hours). Accordingly, as illustrated in FIG. 2E, operations of comparing (Block 230A of FIG. 2B) may include (i) identifying/storing (Block 230A-1) value(s) of the actual power output P as indicated in the data D, then/concurrently (ii) determining (Block 230A-2) the expected power output, and then (iii) comparing (Block 230A-3) the actual power output P with the expected power output. The operations of FIG. 2E may be performed using, for example, a processor 150 and a memory 170 of a node N.

In some embodiments, operations shown in FIG. 2B may be performed with respect to each inverter I at each plant 120. Accordingly, an individual performance determination can be made for each of the inverters I-1 through I-4 that are shown in FIGS. 1B and 1C. Also, though the inverters I-1 through I-4 are shown at two different plants 120-1 and 120-2, they may alternatively be at four different plants 120, respectively. Alternatively, at least three of the inverters I-1 through I-4 may be at the same plant 120. Moreover, as each plant 120 may have dozens, hundreds, or more inverters I, the operations shown in FIG. 2B may be performed for dozens, hundreds, thousands, or more inverters I.

Referring to FIG. 2C, operations of identifying (Block 230 of FIG. 2A) power output P underperformance may include inputting (Block 231) data D received from plants 120 into a plurality of machine-learning (e.g., deep-learning and/or business-logic) models. Moreover, the operations may include applying (Block 232), using the data D, the machine-learning models to each inverter I for which the data D is received. Applying the machine-learning models may include accounting for various plant information/conditions, such as cloud cover, particulates, time of year (e.g., length of daylight per day), that may affect solar power system performance. In some embodiments, the machine-learning (and/or business-logic) models may perform the operations shown in FIG. 2B for each of the inverters I. Moreover, in some embodiments, one of the machine-learning models may be an artificial neural network that is used only after computing a difference between actual power output P and expected power output.

A node N at a data center 130 may host one or more machine-learning (and/or business-logic) models. For example, three deep-learning (and/or business-logic) models may be applied to each inverter I, and the three models may be hosted on (i) the same node N at a data center 130, (ii) different nodes N at the same data center 130, or (iii) different nodes N at two or more different data centers 130.

Referring to FIG. 2D, operations of applying (Block 232 of FIG. 2C) the machine-learning (and/or business-logic) models may include classifying (Block 232-1), by the machine-learning (and/or business-logic) models, a difference between actual power output P by an inverter I and its expected power output. For example, the classifying may include comparing (a) first data D indicating actual power output P by an inverter I during a first time period with (b) its expected power output during the first time period. The classifying may further include comparing (c) second data D indicating actual power output P by the inverter I during a second time period with (d) its expected power output during the second time period. In some embodiments, the time periods may each comprise a plurality of minutes. As an example, the first time period may be a ten-minute period during a morning of a day, and the second time period may be a ten-minute period during an afternoon of the day.

In some embodiments, the machine-learning (and/or business-logic) model(s) may be used to identify ongoing equipment issues/problems (e.g., events) by intelligently clustering classifications over multiple days for a particular inverter I (or other equipment) at a particular plant 120. Such clustering is discussed in greater detail herein with respect to FIG. 3.

Referring still to FIG. 2D, operations of applying (Block 232 of FIG. 2C) the machine-learning (and/or business-logic) models may also include further classifying (Block 232-2) the difference by providing a plurality of outputs from the machine-learning (and/or business-logic) models, respectively, to a further model that processes (e.g., using linear regression) the outputs and provides a final classification for the inverter I. The further model may be, for example, a machine-learning (and/or business-logic) model that is hosted by a node N at a data center 130. Depending on the magnitude of the difference, it may be classified, using one or more operations of FIG. 2D, broadly as (i) underperformance occurring at the inverter I or (ii) a complete power output failure occurring at the inverter I. Moreover, underperformance may be more precisely classified, using operation(s) of FIG. 2D, into one or more among a plurality of different predetermined types/classifications (e.g., causes) of underperformance. For example, classifications of underperformance may include (a) bad weather, such as rain and/or clouds, (b) shade, which may be due to trees and/or the time of day, (c) underperformance by the inverter I itself (e.g., by underperforming circuitry of the inverter I), (d) complete failure of the inverter I (i.e., the inverter I is down), and (e) underperformance by a tracker 127 (FIG. 1C). In some embodiments, soiling (e.g., the presence of dirt, pollen, animal waste, or other debris) on a panel/array A (FIGS. 1B and 1C) may be identified as a cause of underperformance.

FIG. 3 is a screenshot of a GUI 300 of an electronic device 102 (FIG. 1A or FIG. 11) that is communicatively coupled to a communications network 115 (FIG. 1A) or to a different communications network. The GUI 300 may be a GUI that is displayed on a display screen DS (e.g., a touchscreen and/or a computer monitor) of the electronic device 102. In some embodiments, a human user may use the GUI 300 to view a performance summary for an inverter I (FIG. 1B or FIG. 1C). For example, the user may select the performance summary by entering (e.g., typing) a number, which identifies the inverter I, in a text box of the GUI 300. As another example, the user may use the GUI 300 to select the performance summary via (i) a list of inverters I, (ii) a geographic information system (“GIS”) map of inverters I, or (iii) a link in an alert message for the inverter I. The user may view/use the GUI 300 in an Internet browser or in a mobile application. Additionally or alternatively, the GUI 300 may use a custom application programming interface (“API”) to symbiotically share (e.g., transmit and/or receive) data with other applications not defined herein.

Moreover, the GUI 300 may, in some embodiments, display an indication of a priority level 370 (e.g., high, low, or moderate) of an event loss for the inverter I. The priority level 370 may be based on, for example, the severity/degree of the event loss and/or the geographic location of the inverter I. Accordingly, the user can use the GUI 300 to focus on the most impactful loss events, which can help to save time in the field identifying and categorizing issues.

The performance summary may include (a) an identification number of the inverter I, (b) an indication of a geographic location of a plant 120 (FIG. 1A) where the inverter I is located, and/or (c) an indication of how recently (e.g., one minute ago) updated data D (FIG. 1D or FIG. 1E) indicating power output P (FIGS. 1B and 1C) by the inverter I was received from the plant 120. Moreover, the performance summary may indicate a current performance level 310, such as underperforming, complete power output failure, or performing adequately. If power output P underperformance is occurring at the inverter I, the performance summary may further indicate one or more among a plurality of predetermined classifications 320 (e.g., bad weather and/or shade) that categorize the underperformance. In some embodiments, the indication of underperformance classification(s) 320 may include a button 325 that the user can select to view more details of the underperformance classification(s) 320.

The performance summary may, in some embodiments, indicate historical power output P performance 330 at the inverter I. As an example, the performance summary may indicate the number of time periods in the last twenty-four hours (or the last week or month) in which power output P underperformance has occurred at the inverter I. To view more details of historical performance at the inverter I, the user may select a button 335. Such details may be used by machine learning or business logic to generate predictive maintenance information, such as by leveraging failure patterns from historical data to predict the duration, energy loss, and/or revenue loss attributed to an ongoing equipment issue. Accordingly, the button 335 may, in some embodiments, be used to view predictive maintenance information that is based on historical data.

In some embodiments, the user may select different ways to view power output P performance occurring at the inverter I via the GUI 300. For example, the GUI 300 may provide the user with options to (i) view 340 the power output P performance occurring at all inverters I that are at a particular plant 120, (ii) view 350 a list of inverters I at which power output P underperformance is occurring, and/or (iii) view 360 a GIS map of inverters I at which power output P underperformance is occurring.

Moreover, referring back to FIG. 2A, one or more indications (e.g., classifications) of power output P performance occurring at the inverter I may be provided (Block 240) to the GUI 300 in response to an identification of underperformance (Block 230) and/or in response to a service request. For example, the performance indication(s) may be provided to the GUI 300 from a node N (or multiple nodes N) hosting one or more machine-learning (and/or business-logic) models that are applied with respect to the inverter I. The node(s) N may also provide work-order management functionality by tracking the status 380 of service requests (e.g., for a particular inverter I or generally for a particular plant 120) and outputting the status 380 to the GUI 300.

In some embodiments, machine learning or business logic may be used to identify ongoing equipment issues (e.g., events) by intelligently clustering multiple days' classifications for a particular inverter I (or other equipment) at a particular plant 120. For example, machine learning or business logic may be used to (i) generate a first classification for the inverter I on a first day, (ii) generate a second classification for the inverter I on a second day that is different from the first day, (iii) cluster (e.g., aggregate) the first and second classifications together to generate a clustered classification, and (iv) identify that an ongoing problem is occurring with the inverter I based on the clustered classification. As an example, the second classification may be a repeat occurrence of the first classification. Accordingly, a repeated (or otherwise clustered) classification for the inverter I can be used to identify an ongoing issue.

Using this clustering technique, one or more of the following items/information can be identified/generated with respect to the issue: (i) the date that the issue begins, (ii) the duration of the issue, (iii) energy loss that has already resulted from the issue, (iv) a forecast of future energy loss resulting from the issue, (v) revenue loss that has already resulted from the issue, (vi) a forecast of future revenue loss resulting from the issue, (vii) prioritization of different issues (e.g., an order in which the issues will be addressed), and (viii) grouping of multiple issues by location to help reduce repair time. Details regarding the identified/generated item(s) can, in some embodiments, be viewed by a user by selecting the button 325.

Embodiments of the present inventive concepts may provide a number of advantages. These advantages include providing a platform/tool that allows data D (FIGS. 1D and 1E) to be received from dozens, hundreds, thousands or more inverters I (FIGS. 1B and 1C) multiple times each day (e.g., at regular intervals each hour) and analyzed to identify and classify power output P (FIGS. 1B and 1C) underperformance. By contrast, conventional systems may not receive such data D, or may receive it but not identify and classify underperformance. For example, in contrast with a supervisory control and data acquisition (“SCADA”) system, which may use some of the same data, the present inventive concepts may primarily use the data D to identify (a) underperformance, in addition to identifying instances of (b) complete failure and quantifying the associated lost energy.

For example, the present inventive concepts may use artificial intelligence (e.g., machine-learning and/or business-logic models) to identify underperformance losses and prioritize the losses based on impact, such as energy (e.g., in kilowatts) lost. As an example, artificial-intelligence models can use near-real-time data, which may be no more than ten, fifteen, or twenty minutes old, to determine the type and impact of each loss. The models may process hundreds of millions of rows of data in a big-data/multi-node-computing environment to identify and classify the losses. Outputs of the models may enable strategic actions for addressing loss issues, including grouping losses and issuing service requests to field crews.

Moreover, a GUI 300 (FIG. 3) may be used that allows for losses to be visualized, and/or aggregated hierarchically, by (i) inverter I, (ii) plant 120 (FIG. 1A), (iii) geographic area, and/or (iv) GIS views. For example, a mobile electronic device 102 (FIG. 3) can use GIS views to help understand where loss events occur. Artificial-intelligence (and/or business-logic) models, which may include GIS analytics, may relate losses to specific assets at plant(s) 120 and may allow for service requests for the plant(s) 120 to be created and tracked in a work-order management system.

To enhance the security of communications received from nodes N (FIGS. 1D and 1E), which may be IOT devices, that are at plants 120, security authentication may occur iteratively. For example, a new token T (FIGS. 1D and 1E) may be required for each transmission by an IOT device to a data center 130.

The present inventive concepts have been described above with reference to the accompanying drawings. The present inventive concepts are not limited to the illustrated embodiments. Rather, these embodiments are intended to fully and completely disclose the present inventive concepts to those skilled in this art. In the drawings, like numbers refer to like elements throughout. Thicknesses and dimensions of some components may be exaggerated for clarity.

Spatially relative terms, such as “under,” “below,” “lower,” “over,” “upper,” “top,” “bottom,” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “under” or “beneath” other elements or features would then be oriented “over” the other elements or features. Thus, the example term “under” can encompass both an orientation of over and under. The device may be otherwise oriented (rotated 90 degrees or at other orientations) and the spatially relative descriptors used herein interpreted accordingly.

Herein, the terms “attached,” “connected,” “interconnected,” “contacting,” “mounted,” and the like can mean either direct or indirect attachment or contact between elements, unless stated otherwise.

Well-known functions or constructions may not be described in detail for brevity and/or clarity. As used herein the expression “and/or” includes any and all combinations of one or more of the associated listed items.

The terminology used herein is for the purpose of describing particular embodiments only and is not intended to be limiting of the present inventive concepts. As used herein, the singular forms “a,” “an,” and “the” are intended to include the plural forms as well, unless the context clearly indicates otherwise. It will be further understood that the terms “comprises,” “comprising,” “includes,” and/or “including” when used in this specification, specify the presence of stated features, operations, elements, and/or components, but do not preclude the presence or addition of one or more other features, operations, elements, components, and/or groups thereof.

It will also be understood that although the terms “first” and “second” may be used herein to describe various elements, these elements should not be limited by these terms. These terms are only used to distinguish one element from another element. Thus, a first element could be termed a second element, and similarly, a second element may be termed a first element without departing from the teachings of present inventive concepts.

Example embodiments of the present inventive concepts may be embodied as nodes, devices, apparatuses, and methods. Accordingly, example embodiments of present inventive concepts may be embodied in hardware and/or in software (including firmware, resident software, micro-code, etc.). Furthermore, example embodiments of present inventive concepts may take the form of a computer program product comprising a non-transitory computer-usable or computer-readable storage medium having computer-usable or computer-readable program code embodied in the medium for use by or in connection with an instruction execution system. In the context of this document, a computer-usable or computer-readable medium may be any medium that can contain, store, communicate, or transport the program for use by or in connection with the instruction execution system, apparatus, or device.

The computer-usable or computer-readable medium may be, for example but not limited to, an electronic, magnetic, optical, electromagnetic, infrared, or semiconductor system, apparatus, or device. More specific examples (a nonexhaustive list) of the computer-readable medium would include the following: an electrical connection having one or more wires, a portable computer diskette, a random access memory (“RAM”), a read-only memory (“ROM”), an erasable programmable read-only memory (“EPROM” or Flash memory), an optical fiber, and a portable compact disc read-only memory (“CD-ROM”). Note that the computer-usable or computer-readable medium could even be paper or another suitable medium upon which the program is printed, as the program can be electronically captured, via, for instance, optical scanning of the paper or other medium, then compiled, interpreted, or otherwise processed in a suitable manner, if necessary, and then stored in a computer memory.

Example embodiments of present inventive concepts are described herein with reference to flowchart and/or block diagram illustrations. It will be understood that each block of the flowchart and/or block diagram illustrations, and combinations of blocks in the flowchart and/or block diagram illustrations, may be implemented by computer program instructions and/or hardware operations. These computer program instructions may be provided to a processor of a general purpose computer, a special purpose computer, or other programmable data processing apparatus to produce a machine, such that the instructions, which execute via the processor of the computer or other programmable data processing apparatus, create/use circuits for implementing the functions specified in the flowchart and/or block diagram block or blocks.

These computer program instructions may also be stored in a computer usable or computer-readable memory that may direct a computer or other programmable data processing apparatus to function in a particular manner, such that the instructions stored in the computer usable or computer-readable memory produce an article of manufacture including instructions that implement the functions specified in the flowchart and/or block diagram block or blocks.

The computer program instructions may also be loaded onto a computer or other programmable data processing apparatus to cause a series of operational steps to be performed on the computer or other programmable apparatus to produce a computer implemented process such that the instructions that execute on the computer or other programmable apparatus provide steps for implementing the functions specified in the flowchart and/or block diagram block or blocks.

That which is claimed is:

1. A method comprising:
receiving, via a communications network, data regarding a plurality of solar power plants that comprise a plurality of solar inverters;
identifying, based on the data, power output underperformance occurring at a first of the solar inverters; and
providing an indication of the power output underperformance to a graphical user interface (GUI) of an electronic device that is communicatively coupled to the communications network or to a different communications network.

2. The method of claim 1,
wherein the identifying comprises:
comparing, based on the data, actual power output by the first of the solar inverters with expected power output by the first of the solar inverters; and
determining, based on the comparing, that the actual power output is lower than the expected power output, and
wherein the expected power output is determined after receiving the data.

3. The method of claim 2, further comprising identifying adequate power output performance occurring at a second of the solar inverters by:
comparing, based on the data, actual power output by the second of the solar inverters with expected power output by the second of the solar inverters; and
determining, based on the comparing, that the actual power output by the second of the solar inverters meets or exceeds the expected power output by the second of the solar inverters.

4. The method of claim 3, further comprising identifying complete power output failure by a third of the solar inverters.

5. The method of claim 4, wherein the identifying the complete power output failure comprises:
comparing, based on the data, actual power output by the third of the solar inverters with expected power output by the third of the solar inverters; and
determining, based on the comparing, that the actual power output by the third of the solar inverters is zero and that the expected power output by the third of the solar inverters is greater than zero.

6. The method of claim 5, further comprising identifying power output underperformance occurring at a fourth of the solar inverters by:
comparing, based on the data, actual power output by the fourth of the solar inverters with expected power output by the fourth of the solar inverters; and
determining, based on the comparing, that the actual power output by the fourth of the solar inverters is lower than the expected power output by the fourth of the solar inverters.

7. The method of claim 6, wherein the first through fourth solar inverters are at different first through fourth of the solar power plants, respectively.

8. The method of claim 6, wherein at least three of the first through fourth solar inverters are at the same one of the solar power plants.

9. The method of claim 1, wherein the identifying comprises:
inputting the data into a plurality of deep-learning and/or business-logic models; and
applying, using the data, the deep-learning and/or business-logic models to each of the solar inverters.

10. The method of claim 9, wherein the applying comprises classifying, by the deep-learning and/or business-logic models, a difference between actual power output by the first of the solar inverters and expected power output by the first of the solar inverters.

11. The method of claim 10, wherein the classifying comprises:
comparing first data indicating actual power output by the first of the solar inverters during a first time period with expected power output by the first of the solar inverters during the first time period; and
comparing second data indicating actual power output by the first of the solar inverters during a second time period with expected power output by the first of the solar inverters during the second time period.

12. The method of claim 11,
wherein the first and second time periods each comprise a plurality of minutes, and
wherein the data comprises solar irradiance data that indicates solar irradiance at a solar array that is coupled to the first of the solar inverters.

13. The method of claim 10, wherein the classifying comprises providing a plurality of outputs from the deep-learning and/or business-logic models, respectively, to a further model that processes the outputs and provides a final classification for the first of the solar inverters.

14. The method of claim 10, wherein the classifying comprises:
generating a first classification for the first of the solar inverters on a first day;
generating a second classification for the first of the solar inverters on a second day that is different from the first day;
clustering the first and second classifications together to generate a clustered classification; and
identifying that an ongoing problem is occurring with the first of the solar inverters based on the clustered classification.

15. The method of claim 14,
wherein the second classification is a repeat of the first classification, and
wherein the identifying that the ongoing problem is occurring comprises:
using the clustered classification to identify:
a date that the ongoing problem began;
a duration of the ongoing problem;
an energy loss that has already resulted from the ongoing problem;
a forecast of future energy loss resulting from the ongoing problem;
revenue loss that has already resulted from the ongoing problem;
a forecast of future revenue loss resulting from the ongoing problem;
prioritization of the ongoing problem relative to another ongoing problem; and/or
a grouping of multiple ongoing problems by location.

16. The method of claim 1, wherein the data is received via the communications network from a plurality of nodes that are adjacent and coupled to the solar inverters, respectively.

17. The method of claim 16,
wherein the communications network comprises a cellular network or a fiber network, and
wherein the method further comprises:
sending, via the cellular network or the fiber network, a plurality of authentication tokens to the nodes, or to central nodes that are communicatively coupled to the nodes, before the data is received; or
sending, via the cellular network or the fiber network, a command to increase or decrease power that is output by the first of the solar inverters, in response to the identifying.

18. The method of claim 1, wherein the data comprises current-transducer data and/or tracking-system data.

19. A method comprising:
receiving, via a communications network, first and second actual power output data indicating actual power output by first and second solar inverters, respectively, that are at a first solar power plant;
receiving, via the communications network, third and fourth actual power output data indicating actual power output by third and fourth solar inverters, respectively, that are at a second solar power plant;
comparing, as a first comparison, the first actual power output data with first expected power output data indicating expected power output by the first solar inverter;
comparing, as a second comparison, the second actual power output data with second expected power output data indicating expected power output by the second solar inverter;
comparing, as a third comparison, the third actual power output data with third expected power output data indicating expected power output by the third solar inverter;
comparing, as a fourth comparison, the fourth actual power output data with fourth expected power output data indicating expected power output by the fourth solar inverter; and
identifying, based on the first through fourth comparisons, power output underperformance occurring at one or more of the first through fourth solar inverters.

20. The method of claim 19, further comprising:
using machine learning and/or business logic to classify the power output underperformance into one or more among a plurality of predetermined classifications; and
providing an indication of the power output underperformance to a graphical user interface (GUI) of an electronic device.

21. The method of claim 19,
wherein the first through fourth actual power data are received via the communications network from first through fourth nodes that are adjacent and coupled to the first through fourth solar inverters, respectively,
wherein the communications network comprises a cellular network or a fiber network, and
wherein the method further comprises sending, via the cellular network or the fiber network, authentication tokens to the first through fourth nodes, or to central nodes that are communicatively coupled to the first through fourth nodes, before the first through fourth actual power output data are received.

22. A computer program product comprising:
a non-transitory computer readable storage medium comprising computer readable program code embodied in the medium, the computer readable program code comprising:
computer readable program code configured to apply, using data regarding a plurality of solar inverters that are at a plurality of solar power plants, a machine-learning and/or business-logic model to each of the solar inverters to identify power output underperformance occurring at one or more of the solar inverters.

23. The computer program product of claim 22, wherein the computer readable program code is configured to identify the power output underperformance by:
comparing, as a first comparison, first actual power output data indicating actual power output by a first of the solar inverters that is at a first of the solar power plants with first expected power output data indicating expected power output by the first of the solar inverters;
comparing, as a second comparison, second actual power output data indicating actual power output by a second of the solar inverters that is at the first of the solar power plants with second expected power output data indicating expected power output by the second of the solar inverters;
comparing, as a third comparison, third actual power output data indicating actual power output by a third of the solar inverters that is at a second of the solar power plants with third expected power output data indicating expected power output by the third of the solar inverters;
comparing, as a fourth comparison, fourth actual power output data indicating actual power output by a fourth of the solar inverters that is at the second of the solar power plants with fourth expected power output data indicating expected power output by the fourth of the solar inverters; and
providing, based on the first through fourth comparisons, an indication of the power output underperformance to a graphical user interface (GUI) of an electronic device.
